(19) United States
(12) Patent Application Publication
(10) Pub. No.: US 2007/0029682 A1
(43) Pub. Date: Feb. 8, 2007

(54) Epoxy resin composition and semiconductor device

(75) Inventors: Takayuki Aoki, Annaka-shi (JP); Toshio Shiobara, Annaka-shi (JP)

Correspondence Address: BIRCH STEWART KOLASCH & BIRCH, PO BOX 747, FALLS CHURCH, VA, 22040-0747, US

(73) Assignee: Shin-Etsu Chemical Co., Ltd., Tokyo (JP)

(21) Appl. No.: 11/498,179

(22) Filed: Aug. 3, 2006

(30) Foreign Application Priority Data
Aug. 5, 2005 (JP) 2005-227338

(51) Int. Cl. H01L 23/29

(52) U.S. Cl. 257/793

(57) ABSTRACT

An epoxy resin composition is provided comprising (A) an epoxy resin, (B) a phenolic resin curing agent, (C) an inorganic filler, (D) a cure accelerator, (E) an adhesion promoter, and (F) a metal oxide. The metal oxide (F) is a combination of a magnesium/aluminum ion exchanger, a hydrotalcite ion exchanger, and a rare earth oxide in a ratio of 0.5-20:0.5-20:0.01-10 pbw, relative to 100 pbw of epoxy resin (A) and curing agent (B) combined.

### CROSS-REFERENCE TO RELATED APPLICATION

This non-provisional application claims priority under 35 U.S.C. §119(a) on Patent Application No. 2005-227338 filed in Japan on August 5, 2005, the entire contents of which are hereby incorporated by reference.

### TECHNICAL FIELD

This invention relates to an epoxy resin composition for semiconductor encapsulation which is highly reliable in that the cured composition with which a semiconductor device is encapsulated restrains corrosion of copper wiring, migration of copper, and formation of intermetallic compounds at the joint between aluminum and gold. It also relates to a semiconductor device encapsulated with a cured product of the composition.

### BACKGROUND ART

The current high-speed operation of semiconductor devices has brought a transition of wiring from aluminum to copper. Since copper is more susceptible to oxidation and corrosion than aluminum, the use of copper requires more attention. Particularly when copper wires, interconnections, and lead frames are used, migration occurs with the aid of phosphate, nitrate and sulfate ions.

Intermetallic compounds form at the joint between aluminum and gold and can deteriorate semiconductor characteristics. Formation of such intermetallic compounds is attributable to the use of bromine compounds and antimony oxide as the flame retardant as described in Microelectronics Reliability, 40 (2000), 145-153.

To avoid deterioration of semiconductor characteristics, epoxy resin compositions which are free of bromine compounds or antimony oxide have been developed. Even in semiconductor devices encapsulated with epoxy resin compositions of this type, intermetallic compounds can sometimes form to detract from the semiconductor characteristics.

Specifically, when a semiconductor device encapsulated with a halogen- and antimony compound-free epoxy resin composition in the cured state is held at high temperatures of 170° C. or higher for a long term, intermetallic compounds form at the joint between aluminum and gold to increase the electrical resistance. Such a failure occurs because nitrogen or sulfur atom-containing compounds used as the adhesion promoter can be oxidized and degraded at high temperature to generate sulfate, nitrate or phosphate ions or organic acids. Of the organic acids, low molecular weight acids such as formic acid and acetic acid are problematic.

As a result of ions of these species being generated, the cured product becomes acidic. Under the circumstances, penetration of moisture into the cured product facilitates corrosion of aluminum electrodes and migration of silver and copper.

It is well known to use ion trapping agents in order to trap ions of these species. Most trapping agents, which have trapped ions, allow metal ions to leach out. Since metal ions have electric charges, some become one of the causes of increased leak current. Reference should be made to Japanese Patent No. 2501820, 2519277, 2712898, and 3167853, JP-B 06-051826, JP-A 09-118810, JP-A 10-158360, JP-A 11-240937, JP-A 11-310766, JP-A 2000-159520, JP-A 2000-230110, and JP-A 2002-080566.

### DISCLOSURE OF THE INVENTION

An object of the present invention is to provide an epoxy resin composition which is improved in reliability in that when a semiconductor device is encapsulated with the cured composition, the cured composition is capable of suppressing corrosion of copper wiring, migration of copper, and formation of intermetallic compounds at the joint between aluminum and gold. A further object is to provide a semiconductor device encapsulated with a cured product of the composition.

Studying various ion exchangers and metal oxides, the inventors have found that by using specific ion exchangers selected from those known in the art in combination with a lo lanthanoid metal oxide, ionic species having negative impact on the reliability of semiconductor devices can be fixed. As a result, semiconductor devices having improved reliability are obtainable.

More specifically, continuing the research work for preventing migration of copper and formation of intermetallic compounds, the inventors have found that an epoxy resin composition comprising (A) an epoxy resin, (B) a phenolic resin curing agent, (C) an inorganic filler, (D) a cure accelerator, (E) an adhesion promoter, and (F) a metal oxide becomes an effective encapsulant when the metal oxide (F) is a combination of (a) a magnesium/aluminum ion exchanger, (b) a hydrotalcite ion exchanger, and (c) a rare earth oxide in a ratio (a):(b):(c) of 0.5 to 20 parts by weight:0.5 to 20 parts by weight:0.01 to 10 parts by weight, relative to 100 parts by weight of the epoxy resin (A) and the curing agent (B) combined; that a semiconductor device encapsulated with this composition is fully reliable in that corrosion of copper wiring, migration of copper, and formation of intermetallic compounds at the joint between aluminum and gold are suppressed. Better results are obtained if the epoxy resin composition used contains each up to 5 ppm of phosphate, nitrate, and sulfate ions, as measured by the water extraction method to be described later.

Accordingly, the present invention provides an epoxy resin composition comprising (A) an epoxy resin, (B) a phenolic resin curing agent, (C) an inorganic filler, (D) a cure accelerator, (E) an adhesion promoter, and (F) a metal oxide. The metal oxide (F) comprises (a) a magnesium/aluminum ion exchanger, (b) a hydrotalcite ion exchanger, and (c) a rare earth oxide in a ratio (a):(b):(c) of 0.5 to 20 parts by weight:0.5 to 20 parts by weight:0.01 to 10 parts by weight, relative to 100 parts by weight of the epoxy resin (A) and the curing agent (B) combined. Also contemplated herein is a semiconductor device encapsulated with a cured product of the epoxy resin composition.

### BENEFITS OF THE INVENTION

When used for the encapsulation of a semiconductor device, the epoxy resin composition of the invention provides a cured product capable of suppressing corrosion of copper wiring, migration of copper, and formation of intermetallic compounds at the joint between aluminum and gold. Thus the semiconductor device encapsulated with the cured epoxy resin composition has improved reflow crack resistance, moisture resistance, and temperature reliability.

### DESCRIPTION OF THE PREFERRED EMBODIMENTS

The epoxy resin composition of the invention for semiconductor encapsulation comprises (A) an epoxy resin, (B) a phenolic resin curing agent, (C) an inorganic filler, (D) a cure accelerator, (E) an adhesion promoter, and (F) a metal oxide.

A. Epoxy resin

Illustrative examples of suitable epoxy resins used in the present invention include phenol novolac type epoxy resins, cresol novolac type epoxy resins, naphthalene ring-containing epoxy resins, phenol aralkyl type epoxy resins, biphenyl type epoxy resins, alicyclic epoxy resins, heterocyclic epoxy resins, bisphenol A type epoxy resins, and bisphenol F type epoxy resins. Preferably, halogenated epoxy resins are excluded.

In the present invention, preferred are epoxy resins having the following general formula (1): 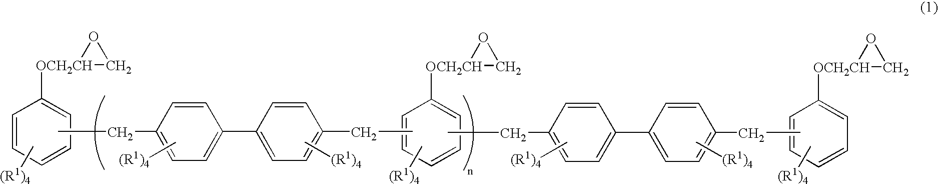
wherein R¹, which may be the same or different, is an atom or a group selected from the group consisting of hydrogen atoms, C₁-C₄ alkyl groups such as methyl, ethyl, propyl, isopropyl, n-butyl, isobutyl, and tert-butyl, and phenyl groups, and n is an integer of 0 to 10.
B. Phenolic Resin Curing Agent

Illustrative examples of phenolic resins used in the present invention as a curing agent for the epoxy resin (A) include phenolic resins having the general formula (2): 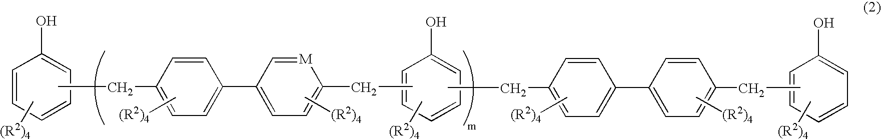
wherein R², which may be the same or different, is an atom or a group selected from the group consisting of hydrogen atoms, C₁-C₄ alkyl groups such as methyl, ethyl, propyl, isopropyl, n-butyl, isobutyl, and tert-butyl, and phenyl groups, and m is an integer of 0 to 10. Also included are naphthalene ring-containing phenolic resins, phenol aralkyl type phenolic resins, biphenyl type phenolic resins, alicyclic phenolic resins, heterocyclic phenolic resins, bisphenol A type phenolic resins, and bisphenol F type phenolic resins. These phenolic resins may be used alone or in combination of two or more.

No particular limit is imposed on the blending proportion of epoxy resin (A) and phenolic resin curing agent (B). The phenolic resin is preferably used in such amounts that the molar ratio of phenolic hydroxyl groups in the curing agent to epoxy groups in the epoxy resin is from 0.5 to 1.5, and more preferably from 0.8 to 1.2. A molar ratio of less than 0.5 or more than 1.5 may break the balance between epoxy groups and phenolic hydroxyl groups, resulting in some cured products having unsatisfactory properties.

C. Inorganic Filler

The inorganic filler (C) used in the invention may be any suitable inorganic filler commonly used in resin compositions. Illustrative examples include silicas such as fused silica and crystalline silica, alumina, silicon nitride, aluminum nitride, boron nitride, titanium oxide, and glass fibers. Of these, spherical fused silica and alumina are preferred, with those having a mean particle size of 5 to 30 μm being desirable for moldability and fluidity.

It is noted that the mean particle size can be determined as the weight average value or median diameter by the laser light diffraction technique, for example.

In order to impart flame retardance to the epoxy resin composition without halogenated resins or antimony trioxide, the inorganic filler (C) is preferably loaded in an amount of 700 to 1,100 parts, more preferably 750 to 1,000 parts by weight per 100 parts by weight of the epoxy resin (A) and curing agent (B) combined. A composition with less than 700 pbw of the filler may have too high a proportion of resin to retard flame. A composition with more than 1,100 pbw of the filler may have too high a viscosity to mold.

It is noted that the inorganic filler used herein is preferably surface treated beforehand with a coupling agent such as a silane coupling agent or a titanate coupling agent in order to increase the bond strength between the resin and the filler. The preferred coupling agents are silane coupling agents including epoxy silanes such as γ-glycidoxypropyltrimethoxysilane, γ-glycidoxypropylmethyldiethoxysilane, and β-(3,4-epoxycyclohexyl)ethyltrimethoxysilane; amino silanes such as N-(β-aminoethyl)-y-aminopropyltrimethoxysilane, the reaction product of imidazole with γ-glycidoxypropyltrimethoxysilane, γ-aminopropyltriethoxysilane, and N-phenyl-γ-aminopropyltrimethoxysilane; and mercapto silanes such as γ-mercaptosilane and γ-episulfidoxypropyltrimethoxysilane. No particular limitation is imposed on the amount of coupling agent used for surface treatment and the method of surface treatment.

D. Cure Accelerator

The cure accelerator employed in the invention may be any suitable cure accelerator commonly used for encapsulating materials. Examples include 1,8-diazabicyclo[5.4.0]undecene-7,2-methylimidazole, 2-ethyl-4-methylimidazole, triphenylphosphine, tris(alkylphenyl)phosphines, tris(alkoxyphenyl)phosphines, tetraphenylphosphonium tetraphenylborate, 1,4-bis(diphenylphosphino)butane, and the like. These compounds may be used alone or in admixture of two or more. Of these, tris(p-tolyl)phosphine having high activity is preferred.

The cure accelerator may be used in an effective amount for promoting the cure reaction. When the cure accelerator is a phosphorus compound, tertiary amine compound or imidazole compound as exemplified above, it is preferably used in amounts of 0.1 to 5 parts by weight, more preferably 0.5 to 2 parts by weight per 100 parts by weight of the epoxy resin (A) and curing agent (B) combined. Less than 0.1 part by weight of component (D) may result in under-curing whereas more than 5 parts by weight of component (D) may reduce the cure time, leaving unfilled voids.

E. Adhesion Promoter

An adhesion promoter is included in the epoxy resin composition of the invention in order to improve adhesion to metallic lead frames, silicon chips, and silver- or gold-plated surfaces. The preferred adhesion promoters used herein include epoxy resins, phenolic resins, organic thiol compounds, thermoplastic resins, and silane coupling agents, each containing sulfur atoms and/or nitrogen atoms.

Typical examples of the adhesion promoter include thiirane resins in the form of bisphenol A or bisphenol F type epoxy resins in which some epoxy groups (typically about half) are converted to thiirane groups, compounds having a five-membered ring dithiocarbonate group, thiophenol derivatives, triglycidoxyisocyanurate, polyamideimide resins, and polyimide resins, as well as N-(2-aminoethyl)-3-aminopropyltrimethoxysilane, 3-aminopropyltrimethoxysilane, N-phenyl-3-aminopropyltrimethoxysilane, and 3-mercaptopropyltrimethoxysilane.

Ordinary epoxy-containing silanes such as 3-glycidoxypropyltrimethoxysilane may be used in combination with the adhesion promoter (E).

The adhesion promoter (E) is preferably used in an amount of 0.1 to 20 parts by weight, more preferably 0.5 to 10 parts by weight per 100 parts by weight of the epoxy resin (A) and the curing agent (B) combined. Particularly when the adhesion promoter is a silane coupling agent, it is desirably used in an amount of 0.1 to 1 part by weight. Too small amounts of component (E) added may fail to achieve the adhesion-promoting effect whereas too large amounts may detract from curability and fluidity.

When a semiconductor device encapsulated with a cured product of an epoxy resin composition containing the above-described adhesion promoter, but not halogenated compounds and antimony compounds is long held at high temperatures of 170° C. or more, there occur drawbacks including formation of intermetallic compounds at the joint between aluminum and gold and increased electrical resistance. This is because a compound containing nitrogen or sulfur atoms used as the adhesion promoter undergoes oxidative deterioration at the high temperature, and generates sulfate, nitrate or phosphate ions, or even organic acids and the like. It is noted that of the organic acids, lower molecular-weight acids such as formic acid and acetic acid are often unwanted. Due to these ions formed, the cured product becomes acidic. In this situation, penetration of moisture gives rise to the problems of quick corrosion of aluminum electrodes and migration of silver or copper.

F. Metal Oxide For ameliorating such failure, the present invention adds a metal oxide as component (F). An effective metal oxide is an inorganic ion exchanger which is a complex of metal oxides and does not allow metal atoms to leach out. Component (F) is preferably such that extraction water (described below) of a cured product of the epoxy resin composition having component (F) added thereto contains only limited amounts of halide, alkali, sulfate, nitrate, and phosphate ions and is at pH 5.5 to 7.

The metal oxide used is a combination of (a) a magnesium/aluminum ion exchanger, (b) a hydrotalcite ion exchanger, and (c) a rare earth oxide.

a. Magnesium/aluminum Ion Exchanger

Specific examples of the magnesium/aluminum ion exchangers include those compounds having the general formula:
MgₓAl_{y}(OH)_{2x+3y-2z}( CO₃)_{z}·mH₂O
wherein x, y, and z are numbers satisfying: 0<y/x≦1and 0≦z/y<1.5, and m is a positive number. Such a magnesium/aluminum ion exchanger is commercially available as IXE-700F from Toagosei Co., Ltd.

The magnesium/aluminum ion exchanger is desirably included in an amount of 0.5 to 20 parts, more preferably 1.0 to 15 parts by weight per 100 parts by weight of components (A) and (B) combined. Less than 0.5 pbw of the magnesium/aluminum ion exchanger may sometimes fail to achieve the desired ion trapping effect whereas more than 20 pbw may result in under-curing and poor flow.

b. Hydrotalcite Ion Exchanger

The hydrotalcite ion exchangers include many commercially available inorganic ion exchangers, for example, bismuth-based compounds, such as IXE500, IXE550; antimony bismuth-based compounds, such as IXE600, IXE633; zirconium bismuth-based compounds, such as IXE6107, all available from Toagosei Co., Ltd.; hydrotalcite compounds, such as DHT-4A-2 and KW2200 from Kyowa Chemical Industry Co., Ltd.

The hydrotalcite ion exchanger is desirably included in an amount of 0.5 to 20 parts, more preferably 1.0 to 15 parts by weight per 100 parts by weight of components (A) and (B) combined. Less than 0.5 pbw of the hydrotalcite ion exchanger may sometimes fail to achieve the desired ion trapping effect whereas more than 20 pbw may result in under-curing and poor flow.

Using the magnesium/aluminum ion exchanger and the hydrotalcite ion exchanger described above, halide ions and alkali metal ions as detected in the prior art can be reduced.

c. Rare Earth Oxide

Rare earth oxides have a good ability to trap ions, especially phosphate ions, and do not allow metal ions such as La, Y, Gd, Bi, Mg, Al ions to leach out even under high temperature and humidity conditions. Moreover rare earth oxides do not alter the curability of epoxy resin compositions. Thus cured products having improved heat resistance and moisture resistance are obtainable.

Examples of the rare earth oxides include lanthanum oxide, gadolinium oxide, samarium oxide, thulium oxide, europium oxide, neodymium oxide, erbium oxide, terbium oxide, praseodymium oxide, dysprosium oxide, yttrium oxide, ytterbium oxide, and holmium oxide, which are commercially available from Shin-Etsu Chemical Co., Ltd.

The rare earth oxide is preferably added in an amount of 0.01 to 10 parts by weight, more preferably 0.5 to 8 parts by weight per 100 parts by weight of components (A) and (B) combined. Less than 0.01 pbw of the rare earth oxide may fail to exert the desired ion trapping effect whereas more than 10 pbw may detract from fluidity.

It has been found that an epoxy resin composition with improved reliability is obtainable by admixing a combination of (a) magnesium/aluminum ion exchanger, (b) hydrotalcite ion exchanger, and (c) rare earth oxide in a specific ratio. They are used in a ratio (a):(b):(c) of 0.5 to 20 parts by weight:0.5 to 20 parts by weight:0.01 to 10 parts by weight, desirably 1 to 10 parts by weight:1 to 10 parts by weight:0.1 to 6 parts by weight relative to 100 parts by weight of components (A) and (B) combined. By mixing the metal oxides in a ratio within the above range and compounding the mixture in epoxy resin compositions, the desired properties can be obtained.

The epoxy resin composition of the invention comprising the epoxy resin (A), the phenolic resin curing agent (B), the inorganic filler (C), the cure accelerator (D), the adhesion promoter (E), and the metal oxide (F) as essential components may further include various additives, if necessary. Exemplary additives include stress reducing agents such as thermoplastic resins, thermoplastic elastomers, organic synthetic rubbers, and silicones; waxes such as carnauba wax; and coloring agents such as carbon black.

Parting agents may also be used herein and include carnauba wax, rice wax, polyethylene, polyethylene oxide, montanic acid, and montan waxes in the form of esters of montanic acid with saturated alcohols, 2-(2-hydroxyethylamino)ethanol, ethylene glycol, glycerin or the like; stearic acid, stearic esters, stearamides, ethylene bisstearamide, ethylene-vinyl acetate copolymers, and the like, alone or in admixture of two or more.

The parting agent is desirably included in an amount of 0.1 to 5 parts, more preferably 0.3 to 4 parts by weight per 100 parts by weight of components (A) and (B) combined.

Additionally, any prior art well-known silane coupling agents other than component (E), i.e., silane coupling agents containing neither nitrogen atoms nor sulfur atoms may be added to the inventive epoxy resin composition for improving its compatibility.

Examples of the silane coupling agents include γ-glycidoxypropyltrimethoxysilane, γ-glycidoxypropylmethyldiethoxysilane, γ-glycidoxypropyltriethoxysilane, p-styryltrimethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, and γ-acryloxypropyltrimethoxysilane. These coupling agents may be used alone or in admixture of two or more. Of these, γ-glycidoxypropyltrimethoxysilane is preferred because an epoxy resin composition having improved moisture-proof reliability and a minimized loss of bond strength after moisture absorption and deterioration is obtainable.

When the coupling agent is used, the amount thereof is usually 0.1 to 5.0 parts, preferably 0.3 to 3.0 parts by weight per 100 parts by weight of components (A) and (B) combined.

In the epoxy resin compositions of the invention, as long as the objects and benefits of the invention can be achieved, there may be further added flame retardants, for example, phosphorus-based flame retardants such as red phosphorus, phosphate esters, and phosphazene compounds, hydroxides such as aluminum hydroxide and magnesium hydroxide, inorganic compounds such as zinc borate, zinc stannate, and zinc molybdate; and other ion-trapping agents such as zirconium phosphates and bismuth hydroxides. It is understood that antimony compounds such as antimony trioxide are excluded.

The flame retardant is desirably included in an amount of 3 to 50 parts, more preferably 5 to 20 parts by weight per 100 parts by weight of components (A) and (B) combined.

Preparation

The inventive epoxy resin compositions may be prepared as a molding material by compounding components (A) to (F) and other additives, if necessary, in predetermined proportions, intimately mixing these components together in a mixer or the like, then melt mixing the resulting mixture in a hot roll mill, kneader, extruder or the like. The mixture is then cooled and solidified, and subsequently ground to a suitable size, yielding a molding material.

The resulting epoxy resin compositions of the invention can be effectively used as encapsulating materials for various types of semiconductor devices. The encapsulation method most commonly used is low-pressure transfer molding. The epoxy resin composition of the invention is preferably molded and cured at a temperature of about 150 to 185° C. for a period of about 30 to 180 seconds, followed by post-curing at about 150 to 185° C. for about 2 to 20 hours.

The present invention favors that when the epoxy resin composition is analyzed for impurities by molding and curing the epoxy resin composition into a disc of 3 mm thick and 50 mm diameter, post-curing the disc at 180° C. for 4 hours, holding the disc at 175° C. for 1,000 hours, controlledly grinding the disc into particles having a particle size of 30 to 150 mesh, placing 5 g of the particles and 50 ml of deionized water in a pressure vessel, and allowing extraction to take place at 125° C. under a pressure of 2.2 atm for 20 hours, the resulting extraction water contains phosphate, nitrate, and sulfate ions in amounts of each up to 5 ppm, more preferably up to 3 ppm, when calculated as contents in the epoxy resin composition. Ion contents of more than 5 ppm for each may fail to achieve the desired effects including moisture resistance and high-temperature storage behavior.

Also, the extraction water should desirably have a pH value of 5.5 to 7. The extraction water below pH 5.5 is so acidic that the composition may fail to achieve the desired high-temperature storage behavior. Above pH 7, the desired moisture resistance may be lost.

It is noted that, when analyzed by the above-described extraction method, conventional epoxy resin compositions bearing sulfur atoms and/or nitrogen atoms contain any one of phosphate, nitrate, and sulfate ions in an amount of 5 ppm or more, and the extraction water is at or below pH 5.5.

### EXAMPLE

Examples and Comparative Examples are given below for further illustrating the invention, but are not intended to limit the invention. In Examples, all parts are by weight.

### Examples 1-6 & Comparative Examples 1-4

Epoxy resin compositions for semiconductor encapsulation were prepared by uniformly melt mixing the components shown in Tables 1 and 2 in a hot twin-roll mill, followed by cooling and grinding. The resulting molding compounds were formed into tablets, molded on a low-pressure transfer molding machine at 175° C. and 70 kgf/cm² for 120 seconds, and then post-cured at 180° C. for 4 hours to obtain a cured product. For each specimen, pH, phosphate, nitrate, and sulfate ion contents, glass transition temperature, reflow crack resistance, moisture resistance, and high-temperature storage behavior were evaluated by the following methods. The results are shown in Tables 1 and 2.

The components used are identified below.

Epoxy Resin

(a) epoxy resin of formula (1-1), NC3000CP (Nippon Kayaku Co., Ltd., epoxy equivalent 272) 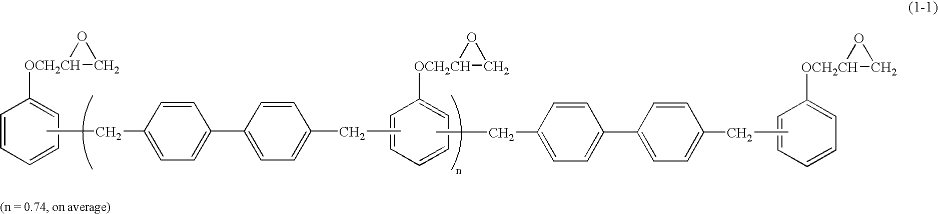
(b) biphenyl type epoxy resin, YX400HK (Yuka-Shell Epoxy Co. Ltd., epoxy equivalent 190)
(c) o-cresol type novolac epoxy resin, EOCN 1020-55 (Nippon Kayaku Co., Ltd., epoxy equivalent 200)
(d) episulfide epoxy resin, ESLV120TE (Tohto Kasei Co., Ltd., epoxy equivalent 250)
   Curing Agent
(e) phenolic resin of formula (2-1), MEH7851L (Meiwa Plastic Industries, Ltd., phenolic hydroxyl equivalent 199) 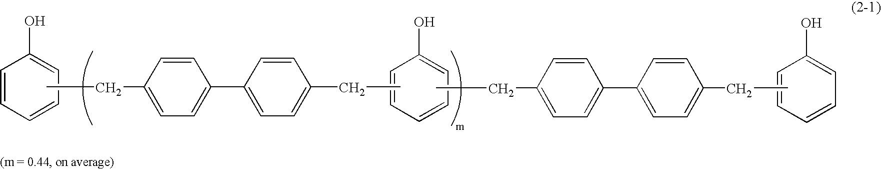
(f) phenol aralkyl resin, MEH-7800SS (Meiwa Plastic Industries, Ltd., phenolic hydroxyl equivalent 175)
(g) phenol novolac resin, DL-92 (Meiwa Plastic Industries, Ltd., phenolic hydroxyl equivalent 110)
   Inorganic Filler

spherical fused silica

(Tatsumori K.K., mean particle size 15 μm)

Curing Accelerator

(h) triphenyl phosphine (Hokko Chemical Industry Co., Ltd.)

(i) tetraphenylphosphonium tetraphenylborate (Hokko Chemical Industry Co., Ltd.)

Adhesion promoter

| | |
|---|---|
| KBM-802 | (3-mercaptopropyltrimethoxysilane, |
| | Shin-Etsu Chemical Co., Ltd.) |
| KBM-603 | (N-(2-aminoethyl)-3-aminopropyltrimethoxysilane, |
| | Shin-Etsu Chemical Co., Ltd.) |
| KBM-403 | (glycidoxypropyltrimethoxysilane, |
| | Shin-Etsu Chemical Co., Ltd.) |

Metal oxide

| | |
|---|---|
| (MO-1) | magnesium/aluminum ion exchanger IXE-700F |
| | (Toagosei Co., Ltd.) |
| (MO-2) | hydrotalcite ion exchanger DHT-4A-2 |
| | (Kyowa Chemical Industry Co., Ltd.) |
| (MO-3) | Rare earth oxide: lanthanum (III) oxide |
| | (Shin-Etsu Chemical Co., Ltd.) |

Other Additives
Carbon black:
   Denka Black (Denki Kagaku Kogyo K.K.)
Parting agent:
   carnauba wax (Nikko Fine Products K.K.)
Flame retardant:
   Antimony trioxide Sb₂O₃RX (Sumitomo Metal Mining Co., Ltd.)
   Brominated epoxy resin AER8049 (Asahi Ciba Co., Ltd.)

Properties (i) to (v) of the compositions were measured by the following methods.

(i) pH, Phosphate, Nitrate, and Sulfate Ion Contents

The epoxy resin composition was molded at 175° C. and 70 kgf /cm² for 120 seconds into a disc of 3 mm thick and 50 mm diameter and post-cured at 180° C. for 4 hours, after which the disc was held at 175° C. for 1,000 hours. The disc was controlledly ground into particles having a particle size of 30 to 150 mesh. 5 g of the particles and 50 ml of deionized water were fed into a pressure vessel where extraction was effected at 125° C. for 20 hours. The amounts of impurities, phosphate, nitrate, and sulfate ions in the extracting water were measured, the measured amounts being converted into the values (ppm) based on the epoxy resin composition. The extracting water was also measured for pH. It is noted that the amounts of ions were measured using ion chromatography.

(ii) Glass Transition Temperature (Tg)

Measured using a thermomechanical analyzer TAS200 (Rigaku Corporation).

(iii) Reflow Crack Resistance

The composition was molded at 175° C. and 70 kgf/cm² for 120 seconds into twenty flat packages of 14×20×2.7 mm and post-cured at 180° C. for 4 hours. The packages were held in a temperature/moisture controlled chamber at 85° C. and 85% RH for 168 hours for moisture absorption. The packages were then dipped in a solder bath at a temperature of 260° C. for 30 seconds. The packages were inspected for external cracks and the number of cracks was counted.

(iv) Moisture Resistance

A dummy semiconductor member having aluminum wiring formed on a silicon chip was bonded to a partially gold-plated 42 Alloy lead frame using gold wires of 30 μm diameter. The epoxy resin composition was molded thereon at 175° C. and 70 kgf/cm² for a molding time of 120 seconds into a TSOP package of 1.4 mm thick and post-cured at 180° C. for 4 hours. Twenty packages thus obtained were held in an atmosphere of 140° C. and 85% RH for 500 hours while a DC bias voltage of 5 V was applied thereacross. The number of packages in which aluminum corroded and broke was counted.

(v) High-Temperature Storage Test

A dummy semiconductor member having aluminum wiring formed on a silicon chip was bonded to a partially gold-plated 42 Alloy lead frame using gold wires of 30 μm diameter. The epoxy resin composition was molded thereon at 175° C. and 70 kgf/cm² for a molding time of 120 seconds into a TSOP package of 1.4 mm thick and post-cured at 180° C. for 4 hours. Twenty packages thus obtained were stored in a dryer at 200° C. for 1,000 hours. Thereafter, the cured resin composition was dissolved in fuming nitric acid, and the tensile strength of bond on the chip side was measured. Samples were regarded defective when the tensile strength value dropped below 50% of the initial value, and the number of defective samples was reported.

TABLE 1

| | | | Example | | | | | |
|---|---|---|---|---|---|---|---|---|
| Formulation (pbw) | | | 1 | 2 | 3 | 4 | 5 | 6 |
| (A) | Epoxy resin (a) | | 51 | 51 | 52 | 40 | 26 | 31 |
| | Epoxy resin (b) | | | | | 10 | 26 | 31 |
| | Epoxy resin (c) | | | | | | | |
| | Epoxy resin (d) | | 6 | 6 | 6 | 6 | 6 | 7 |
| (B) | Phenolic resin (e) | | 43 | 43 | 21 | 22 | 29 | |
| | Phenolic resin (f) | | | | 21 | 22 | | |
| | Phenolic resin (g) | | | | | | 13 | 31 |
| (C) | Inorganic filler: | | 800 | 800 | 800 | 800 | 800 | 800 |
| | spherical fused silica | | | | | | | |
| (D) | Cure accelerator (h) | | 0.5 | 0.5 | 0.5 | 0.5 | 0.5 | 0.5 |
| | Cure accelerator (i) | | 1.0 | 1.0 | 1.0 | 1.0 | 1.0 | 1.0 |
| (E) | KBM-802 | | 0.5 | 0.5 | 0.5 | 0.5 | 0.5 | 0.5 |
| | KBM-603 | | 0.5 | 0.5 | 0.5 | 0.5 | 0.5 | 0.5 |
| | KBM-403 | | 1.0 | 1.0 | 1.0 | 1.0 | 1.0 | 1.0 |
| (F) | Magnesium/aluminum ion | | 3 | 6 | 3 | 3 | 10 | 15 |
| | exchanger | | | | | | | |
| | Lanthanoid metal oxide | | 1 | 3 | 2 | 3 | 5 | 4 |
| | Hydrotalcite ion exchanger | | 3 | 4 | 3 | 3 | 8 | 5 |
| Others | Parting agent | | 1.5 | 1.5 | 1.5 | 1.5 | 1.5 | 1.5 |
| | Carbon black | | 1.5 | 1.5 | 1.5 | 1.5 | 1.5 | 1.5 |
| | Brominated epoxy resin | | | | | | | |
| | Antimony trioxide | | | | | | | |
| Results | pH | — | 6.2 | 6.5 | 6.3 | 6.4 | 7.0 | 6.7 |
| | Phosphate ions | ppm | ≦1 | ≦1 | ≦1 | ≦1 | ≦1 | ≦1 |
| | Nitrate ions | ppm | ≦1 | ≦1 | ≦1 | ≦1 | ≦1 | ≦1 |
| | Sulfate ions | ppm | ≦1 | ≦1 | ≦1 | ≦1 | ≦1 | ≦1 |
| | Tg | ° C. | 135 | 130 | 125 | 120 | 125 | 130 |
| | Reflow crack | defective | 0/20 | 0/20 | 0/20 | 0/20 | 0/20 | 0/20 |
| | resistance | samples | | | | | | |
| | Moisture | defective | 0/20 | 0/20 | 0/20 | 0/20 | 0/20 | 0/20 |
| | resistance | samples | | | | | | |
| | High-temperature | defective | 0/20 | 0/20 | 0/20 | 0/20 | 0/20 | 0/20 |
| | storage test | samples | | | | | | |

TABLE 2

| | | | Comparative Example | | | |
|---|---|---|---|---|---|---|
| | Formulation (pbw) | | 1 | 2 | 3 | 4 |
| (A) | Epoxy resin (a) | | 51 | 31 | 31 | |
| | Epoxy resin (b) | | | 31 | | |
| | Epoxy resin (c) | | | | 31 | 52 |
| | Epoxy resin (d) | | 6 | 7 | 7 | 6 |
| (B) | Phenolic resin (e) | | 43 | | | |
| | Phenolic resin (f) | | | | | |
| | Phenolic resin (g) | | | 31 | 31 | 34 |
| (C) | Inorganic filler: | | 800 | 800 | 800 | 600 |
| | spherical fused silica | | | | | |
| (D) | Cure accelerator (h) | | 0.5 | 0.5 | 0.5 | 0.5 |
| | Cure accelerator (i) | | 1.0 | 1.0 | 1.0 | 1.0 |
| (E) | KBM-802 | | 0.5 | 0.5 | 0.5 | 0.5 |
| | KBM-603 | | 0.5 | 0.5 | 0.5 | 0.5 |
| | KBM-403 | | 1.0 | 1.0 | 1.0 | 1.0 |
| (F) | Magnesium/aluminum ion exchanger | | | 10 | | |
| | Lanthanoid metal oxide | | | | 1 | |
| | Hydrotalcite ion exchanger | | 5 | 10 | 3 | |
| Others | Parting agent | | 1.5 | 1.5 | 1.5 | 1.5 |
| | Carbon black | | 1.5 | 1.5 | 1.5 | 1.5 |
| | Brominated epoxy resin | | | | | 8 |
| | Antimony trioxide | | | | | 10 |
| Results | pH | — | 4.1 | 4.2 | 5.7 | 4.5 |
| | Phosphate ions | ppm | ≦1 | ≦1 | ≦1 | ≦1 |
| | Nitrate ions | ppm | ≦1 | ≦1 | ≦1 | ≦1 |
| | Sulfate ions | ppm | ≦1 | ≦1 | ≦1 | ≦1 |
| | Tg | ° C. | 135 | 130 | 130 | 150 |
| | Reflow crack resistance | defective | 0/20 | 3/20 | 0/20 | 20/20 |
| | | samples | | | | |
| | Moisture resistance | defective | 10/20 | 6/20 | 12/20 | 20/20 |
| | | samples | | | | |
| | High-temperature | defective | 15/20 | 8/20 | 10/20 | 20/20 |
| | storage test | samples | | | | |

Japanese Patent Application No. 2005-227338 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. An epoxy resin composition comprising (A) an epoxy resin, (B) a phenolic resin curing agent, (C) an inorganic filler, (D) a cure accelerator, (E) an adhesion promoter, and (F) a metal oxide, wherein
the metal oxide (F) comprises
(a) a magnesium/aluminum ion exchanger,
(b) a hydrotalcite ion exchanger, and
(c) a rare earth oxide in a ratio (a):(b):(c) of 0.5 to 20 parts by weight:0.5 to 20 parts by weight:0.01 to 10 parts by weight, relative to 100 parts by weight of the epoxy resin (A) and curing agent (B) combined.

2. The epoxy resin composition of claim 1 wherein the adhesion promoter (E) is at least one compound selected from the group consisting of epoxy resins, phenolic resins, organic thiol compounds, thermoplastic resins, and silane coupling agents, each containing sulfur atoms and/or nitrogen atoms.

3. The epoxy resin composition of claim 2 wherein the adhesion promoter (E) is at least one compound selected from the group consisting of thiirane resins in the form of bisphenol A type epoxy resins or bisphenol F type epoxy resins in which some epoxy groups are converted to thiirane groups, compounds having a five-membered ring dithiocarbonate group, thiophenol derivatives, triglycidoxyisocyanurate, polyamideimide resins, polyimide resins, N-(2-aminoethyl)-3-aminopropyltrimethoxysilane, 3-aminopropyltrimethoxysilane, N-phenyl-3-aminopropyltrimethoxysilane, and 3-mercaptopropyltrimethoxysilane.

4. The epoxy resin composition of claim 1 wherein the adhesion promoter (E) is present in an amount of 0.1 to 20 parts by weight per 100 parts by weight of the epoxy resin (A) and curing agent (B) combined.

5. The epoxy resin composition of claim 1, wherein when the epoxy resin composition is analyzed for impurities by molding and curing the epoxy resin composition into a disc of 3 mm thick and 50 mm diameter, holding the disc at 175° C. for 1,000 hours, controlledly grinding the disc into particles having a particle size of 30 to 150 mesh, placing 5 g of the particles and 50 ml of deionized water in a pressure vessel, and allowing extraction to take place at 125° C. for 20 hours, the resulting extraction water contains phosphate, nitrate, and sulfate ions in amounts of each up to 5 ppm, when calculated as contents in the epoxy resin composition, and is at pH 5.5 to 7.

6. A semiconductor device encapsulated with a cured product of the epoxy resin composition of claim 1.
